(19) United States
(12) Patent Application Publication
(10) Pub. No.: US 2004/0124460 A1
(43) Pub. Date: Jul. 1, 2004

(54) Stack gate electrode suppressed with interface-reaction and method for fabricating semiconductor device having the same

(76) Inventors: Kwan-Yong Lim, Ichon-shi (KR); Heung-Jae Cho, Ichon-shi (KR); Jung-Ho Lee, Ichon-shi (KR)

Correspondence Address: Jacobson Holman, Professional Limited Liability Company, 400 Seventh Street, N.W., Washington, DC, 20004-2218, US

(21) Appl. No.: 10/616,302

(22) Filed: Jul. 10, 2003

(30) Foreign Application Priority Data
Dec. 30, 2002 (KR) 2002-86276

(51) Int. Cl. H01L 29/788

(52) U.S. Cl. 257/321

(57) ABSTRACT

The present invention is related to a stack gate electrode capable of suppressing a formation of a non-uniform silicide layer at an interface between a polysilicon layer and a metal layer during a selective oxidation process and a thermal process both being performed after a gate patterning process and a method for fabricating a semiconductor device including the same. The stack gate electrode includes: a silicon layer; a reaction prevention layer formed on the silicon layer, wherein the reaction prevention layer containing nitrogen and silicon has a surface density of nitrogen above about 1×10¹⁵/cm²; and a metal layer formed on the reaction prevention layer.

### FIELD OF THE INVENTION

The present invention relates to a method for fabricating a semiconductor device; and, more particularly, to a method for fabricating a semiconductor device including a gate electrode.

### DESCRIPTION OF RELATED ARTS

A recent technology in large-scale integration have progressively led widths of a gate electrode and an impurity region used as a source and drain region to be progressively decreased. However, this decrease of the width arises a problem of decreasing an operation speed due to an increased contact resistance of the impurity region and a sheet resistance (Rs) of the gate electrode.

Therefore, wires of constitution elements of a semiconductor device are made of such material having a low resistance as aluminum alloys and tungsten. Also, in case of using polysilicon, a silicide layer is formed to reduce the resistance.

Meanwhile, in a semiconductor device including a gate electrode made of the polysilicon, a gate oxide layer is damaged when the polysilicon layer, i.e., the gate electrode, is etched. Thus, a re-oxidation process selectively etching lateral sides of the polysilicon layer is performed to recover the damaged gate oxide layer while the resistance of the gate electrode is maintained throughout.

Herein, the re-oxidation process to the gate oxide layer recovers a microtrench or damage at the gate oxide layer when the gate electrode is etched. Also, the re-oxidation process oxidizes a remnant polysilicon layer remaining on a silicon substrate and increases a thickness of the gate oxide layer in order to increase reliability.

Particularly, the oxide layer at edges of the gate electrode affects characteristics in a hot carrier, a sub-threshold voltage, a punchthrough and an operation speed of a device based on a thickness and a quality of the oxide layer. A Leakage current and a gate induction drain leakage are examples of the sub-threshold voltage characteristic. Therefore, the re-oxidation process is essential for the above reasons.

Currently, a stack gate structure of W/WN/polysilicon is used to reduce the resistance of the gate electrode.

However, the stack gate structure has several disadvantages of an interface-reaction between the polysilicon layer, the WN layer and the W layer; an abrupt volume expansion because of an oxidation of the W layer; and a particle generation. To overcome the above disadvantages, a selective oxidation process is used. That is, The W and the WN layers are not oxidized but the polysilicon layer and the silicon substrate is oxidized in a hydrogen rich oxidation ambient.

FIG. 1 is a cross-sectional view of a conventional semiconductor device including a metal gate structure, which is shown in a drawing of the U.S. Pat. No. 5,719,410 issued to Suehiro et al. on Feb. 17, 1998.

As shown, a silicon oxide layer 2 is formed on a semiconductor substrate 1. A polysilicon layer 3, a silicon nitride layer 4 and a tungsten layer 5 are sequentially deposited on the silicon oxide layer 2, thereby forming a gate electrode. Herein, the silicon nitride layer 4 is a reformed layer of a tungsten nitride layer and has a surface density of nitrogen below about 8×10¹⁴/cm².

FIG. 2 is a cross-sectional view of another conventional semiconductor device including a metal gate structure which is disclosed in a drawing of the U.S. Pat. No. 6,100,193 issued to Suehiro et al. on Aug. 8, 2000.

As shown, a silicon oxide layer 12 is formed on a semiconductor substrate 11. A polysilicon layer 13, a silicon nitride layer 14 and a tungsten layer 15 are sequentially deposited on the silicon oxide layer 12, whereby a gate electrode is formed. Herein, the silicon nitride layer 14 has a predetermined surface density of nitrogen lower than 8×10¹⁴/cm².

In FIGS. 1 and 2, the density of nitrogen is predetermined to be below 8×10¹⁴/cm² in order to prevent an interface-reaction between the tungsten layer 5 and the silicon nitride layer 14. Also, a thickness of the silicon nitride layer 14 is predetermined to be about 1 nm.

In case that the silicon nitride layer is not formed or the tungsten or tungsten nitride layer is formed on the polysilicon layer with a thickness below 1 nm, a cluster layer of non-uniform tungsten silicide is formed after a thermal process or a selective oxidation process. Also, lateral walls of the tungsten silicide are additionally oxidated or nitridated. After the selective oxidation process and the high thermal process, an interfacial oxide layer or interfacial nitride layer is formed. The interfacial oxide layer or interfacial nitride layer is non-uniform and has a thickness above 2 nm. As a result, each fabricated semiconductor device could not have uniform operational characteristics. Particularly, with respect to a resistance, the interface oxide layer has a higher resistivity than the interface nitride layer. Therefore, the formation of the interfacial oxide layer should be precedently suppressed.

### SUMMARY OF THE INVENTION

It is, therefore, an object of the present invention to provide a method for fabricating a semiconductor device including a stack gate electrode having a reaction prevention layer capable of suppressing an interface-reaction between a polysilicon layer and a metal layer.

It is another object of the present invention to provide a method for fabricating a semiconductor device capable of preventing a formation of a non-uniform silicide layer on an interface between a polysilicon layer and a metal layer during a selective oxidation and a thermal process.

In accordance with an aspect of the present invention, there is provided a stack gate electrode of a semiconductor device, including: a silicon layer; a reaction prevention layer formed on the silicon layer, wherein the reaction prevention layer containing nitrogen and silicon and has a surface density of nitrogen above about 1×10¹⁵/cm²; and a metal layer formed on the reaction prevention layer.

In accordance with another aspect of the present invention, there is also provided a method for fabricating a semiconductor device, including the steps of: forming a semiconductor layer including at least a gate insulation layer; forming a silicon layer on the gate insulation layer; forming a reaction prevention layer on the silicon layer, the reaction prevention layer containing nitrogen and silicon and having a surface density of nitrogen above about 1×10¹⁵/cm²; forming a metal layer on the reaction prevention layer; forming a stack gate electrode by etching sequentially the metal layer, the reaction prevention layer and the silicon layer; and performing a selective oxidation process oxidizing selectively the silicon layer from the stack gate electrode.

### BRIEF DESCRIPTION OF THE DRAWING(S)

The above and other objects and features of the present invention will become apparent from the following description of the preferred embodiments given in conjunction with the accompanying drawings, in which:

FIG. 1 is a cross-sectional view showing a conventional semiconductor device including a metal gate structure;

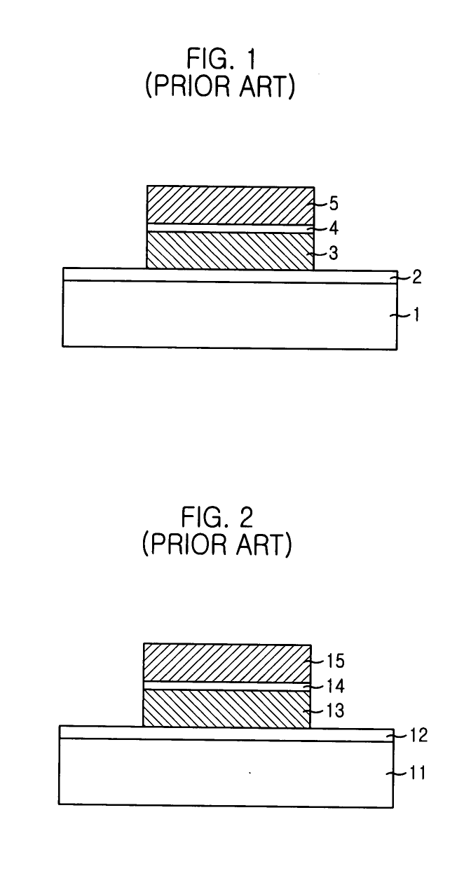

FIG. 2 is a cross-sectional view showing another conventional semiconductor device including a metal gate structure;

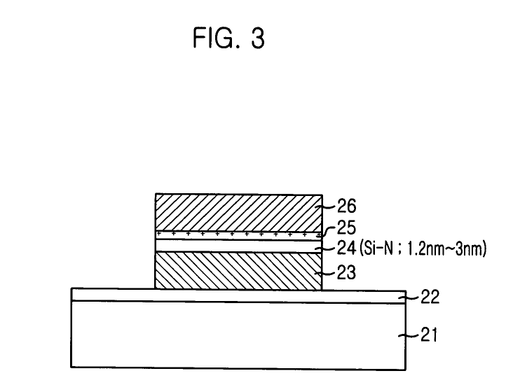

FIG. 3 is a cross-sectional view showing a gate electrode having a stack structure in accordance with a first preferred embodiment of the present invention;

FIGS. 4A to 4D are cross-sectional views showing a method for fabricating a semiconductor device including the gate electrode shown in FIG. 3;

FIG. 5 is a cross-sectional view showing a gate electrode having a stack structure in accordance with a second preferred embodiment;

FIG. 6 is a graph illustrating a result of an XPS analysis on a thermal treatment instigated after depositing a polysilicon layer and performed at a temperature of about 800° C. for about 60 seconds in a NH₃ ambient; and

FIG. 7 are graphs for comparing an XPS analysis result on a stack structure of a tungsten layer, a tungsten nitride layer and a polysilicon layer with that on a stack structure of a tungsten layer, a tungsten nitride layer, a silicon nitride layer and a polysilicon layer.

### DETAILED DESCRIPTION OF THE INVENTION

Hereinafter, there is provided a detailed description on a method for fabricating a semiconductor device including a stack gate electrode capable of suppressing an interface-reaction.

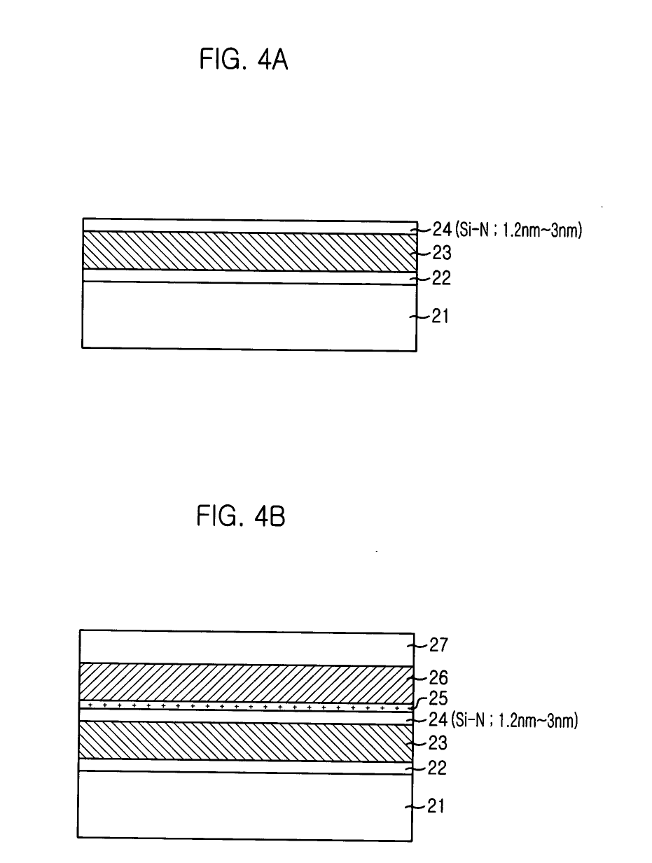

FIG. 3 is a cross-sectional view showing a stack gate electrode of a semiconductor device in accordance with a first preferred embodiment of the present invention.

As shown, a silicon oxide layer 22, which is a gate insulation layer, is formed on a substrate 21. A polysilicon layer 23 is then formed on the silicon oxide layer 22. A silicon nitride layer 24, which is a reaction prevention layer, is formed on the polysilicon layer 23. After forming the silicon nitride layer 24, a tungsten nitride (WNₓ) layer 25 and a tungsten (W) layer 26 are sequentially formed thereon. Herein, the silicon nitride layer 24 is a uniform layer having a density of nitrogen above about 1×10¹⁵/cm², and this density corresponds to a thickness above about 1.2 nm. As a reference, the subscript x of a molecular formula notates the number of atoms presenting in a molecule. Herein, the x of the WNₓ layer 25 ranges between about 0.1 and about 1.1. The tungsten layer 26 is a kind of refractory metal layer.

The silicon nitride layer 24 is formed by any one of the following methods.

First, a plasma nitridation technique including a decoupled plasma nitridation (DPN) or a remote plasma nitridation (RPN) is used to form the silicon nitride layer 24. At this time, the plasma nitridation technique employs a nitrogen containing gas. The nitrogen containing gas is any one selected from a group consisting of NH₃, ND₃, where D is a deuterium, N₂ and NF₃ or a mixed gas of the above provided gases. Also, a temperature of the substrate is maintained in a range from about 0° C. to about 700° C. A RF power is below about 1000 W.

Second, a thermal nitridation technique is used. At this time, the thermal nitridation technique is performed at a temperature ranging from about 750° C. to about 950° C. for about 10 to 100 seconds in an atmosphere of a nitrogen containing gas such as NH₃ and ND₃.

Third, a chemical vapor deposition (CVD) technique is used to form the silicon nitride layer 24.

Forth, an atomic layer deposition (ALD) technique is used.

The silicon nitride layer 24 has a thickness less than about 3 nm.

Meanwhile, the refractory metal layer can use a single atom metal such as Mo, Ta, Ti, Ni and Co in addition to the W. The refractory metal nitride can use such metal nitride as MoNₓ, TaNₓ, TiNₓ and CoNₓ in addition to the WN. Herein, the x, indicating the number of atoms present in a molecule, ranges from about 0.1 to about 1.1.

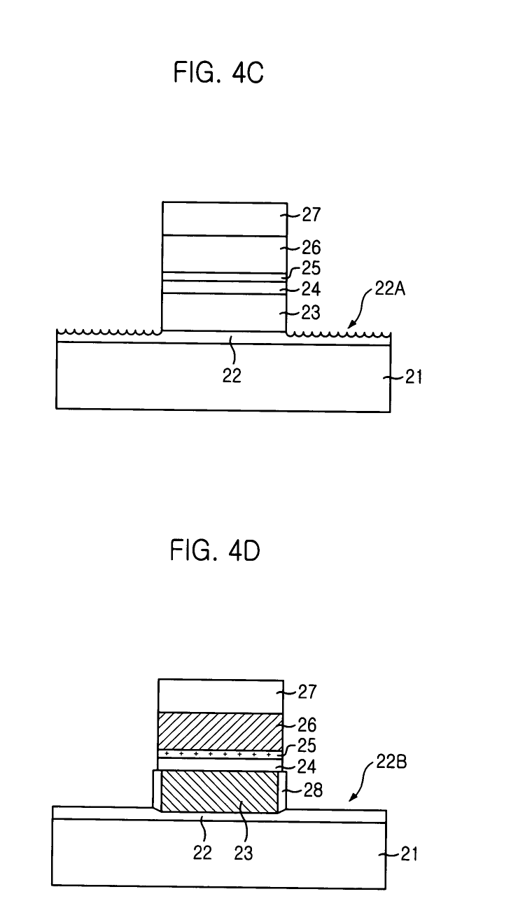

FIGS. 4A to 4D are cross-sectional views showing a method for fabricating a semiconductor device including the stack gate electrode illustrated in FIG. 3.

Referring to FIG. 4A, a silicon oxide layer 22 functioning as a gate insulation layer is formed on a substrate 21. Then, a polysilicon layer 23 doped with an impurity for providing conductivity is deposited on the silicon oxide layer 22. Herein, gate insulation layer can use a high dielectric metal oxide containing Hf or Zr such as SiOₓN_{y}, HfO₂, ZrO₂, Hf—Al—O, Hf-silicate and Zr-silicate. Herein, the x of the SiOₓN_{y} ranges between about 0.03 to about 3 while the y of the SiOₓN_{y} ranges between about 0.03 to about 3. As described above, the subscript x and y denote the number of atoms presenting in a molecule. The polysilicon layer 23 is deposited at a temperature ranging from about 500° C. to about 600° C.

Next, a solution containing HF is used for a cleaning process to remove a native oxide layer formed during the polysilicon layer 23 formation. A silicon nitride layer 24 functioning as a reaction prevention layer is formed on the polysilicon layer 23. At this time, the silicon nitride layer 24 is formed until having a thickness ranging from about 1.2 nm to about 3 nm by employing any one method selected among the plasma nitridation technique, the thermal nitridation, the CVD technique and the ALD technique.

Once the silicon nitride layer 24 is formed with a thickness ranging from about 1.2 nm to about 3 nm, a surface density of nitrogen contained in the silicon nitride layer 24 is greater than about 1×10¹⁵/cm².

Referring to FIG. 4B, a tungsten nitride (WNₓ) layer 25 is deposited on the silicon nitride layer 24, and a tungsten layer 26 is then deposited on the tungsten nitride layer 25. Herein, the x, indicating the number of atoms presenting in a molecule of WNₓ, ranges from about 0.1 to about 1.1.

Next, a hard mask 27 is deposited on the tungsten layer 26.

Referring to FIG. 4C, the hard mask 27 is etched through a photolithography process. The tungsten nitride layer 25, the silicon nitride layer 24 and the polysilicon layer 23 are sequentially etched with use of the etched hard mask 27 as an etch mask so as to form a stack metal gate structure including the polysilicon layer 23, the silicon nitride layer 24, the tungsten nitride layer 25, the tungsten layer 26 and the hard mask 27.

The gate patterning process damages a partial portion of the silicon oxide layer 22 exposed through an etching of the polysilicon layer 23. This damage is denoted as a reference numeral 22A in FIG. 4C.

Referring to FIG. 4D, a re-oxidation process is performed to recover the partial portion 22A of the damaged polysilicon layer 22 as simultaneous as to increase the thickness of the silicon oxide layer 22 at an edge portion of the gate electrode. A selective oxidation process is also performed by selectively oxidizing the polysilicon layer 23 while preventing an oxidation of metal layers, i.e., the tungsten layer 26 and the tungsten nitride layer 26.

The selective oxidation process is performed at a temperature in a range from about 700° C. to about 1100° C. in an atmosphere of a mixture of H₂ and O₂, H₂O and H₂, O₂ and D₂, or D₂O and H₂.

Herein, the above deuterium (D₂) is an isotope of hydrogen, and it has a mass number of 2 and an atomic mass of about 2.01409 amu. The most commonly referred hydrogen (H₂) is a protium of which mass number is 1 and atomic mass is about 1.00794 amu. In case of performing the selective oxidation process in an atmosphere of D₂ having a higher mass and binding energy than those of H₂, it is possible to improve characteristics of a MOSFET device by preventing a deterioration of stress induced leakage current (SILC) characteristic, an induction of charge trapping, a degradation of hot carrier immunity and so forth.

After the selective oxidation process, the damaged silicon oxide layer 22A is reformed to a recovered silicon oxide layer 22B. Also, the recovered silicon oxide layer 22B is thicker than the silicon oxide layer 22 allocated beneath the polysilicon 23 at the edge of the gate electrode. Furthermore, lateral walls of the polysilicon layer 23 are oxidized after the selective oxidation process, whereby a silicon oxide layer 28 is formed.

Although it is not illustrated, an ion implantation process is performed to form a source/drain region with a lightly doped drain (LDD) structure.

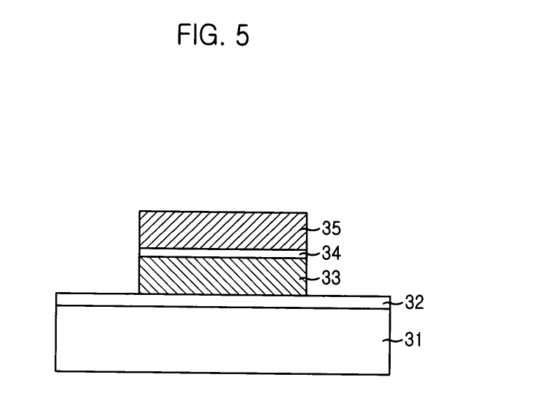

FIG. 5 is a cross-sectional view of a gate electrode having a stack structure in accordance with a second preferred embodiment of the present invention.

As shown, a silicon oxide layer 32, which is a gate insulation layer, is formed on a substrate 31, and a polysilicon layer 33 is then formed on the silicon oxide layer. On top of the polysilicon layer 33, a silicon nitride layer 34, which is a reaction prevention layer, is formed. Then, a tungsten layer 35 is formed on the silicon nitride layer 34. Herein, the silicon nitride layer 34 is uniformly deposited and has a density of nitrogen above about 1×10¹⁵/cm². This value of the nitrogen density corresponds to a thickness above about 1.2 nm. The tungsten layer 35 is a kind of refractory metal.

The silicon nitride layer 34 is formed by any one of the following methods.

First, a plasma nitridation technique including a decoupled plasma nitridation (DPN) or a remote plasma nitridation (RPN) is used to form the silicon nitride layer 34. At this time, the plasma nitridation technique uses a nitrogen containing gas. The nitrogen containing gas is any one selected from a group consisting of NH₃, ND₃, where D is a deuterium, N₂ and NF₃ or a mixed gas of the above provided gases. Also, a temperature of the substrate is maintained in a range from about 0° C. to about 700° C. A RF power is below about 1000 W.

Second, a thermal nitridation technique is used. At this time, the thermal nitridation technique is performed at a temperature ranging from about 750° C. to about 950° C. for about 10 to 100 seconds in an atmosphere of nitrogen containing gas such as NH₃ and ND₃.

Third, a chemical vapor deposition (CVD) technique is used to form the silicon nitride layer 34.

Forth, an atomic layer deposition (ALD) technique is used.

The silicon nitride layer 23 has a thickness less than about 3 nm.

Meanwhile, the refractory metal constituting the metal gate structure can be Mo, Ta, Ti, Ni, Co and so on in addition to the W. The gate insulation layer can use a high dielectric metal oxide containing Hf or Zr such as SiOₓN_{y}, HfO₂, ZrO₂, Hf—Al—O, Hf-silicate and Zr-silicate. Herein, the x of the SiOₓN_{y} ranges between about 0.03 to about 3 while the y ranges between about 0.03 to about 3. As described above, the x and y denotes the number of atoms presenting in a molecule. The polysilicon layer 33 is deposited at a temperature ranging from about 500° C. to about 600° C.

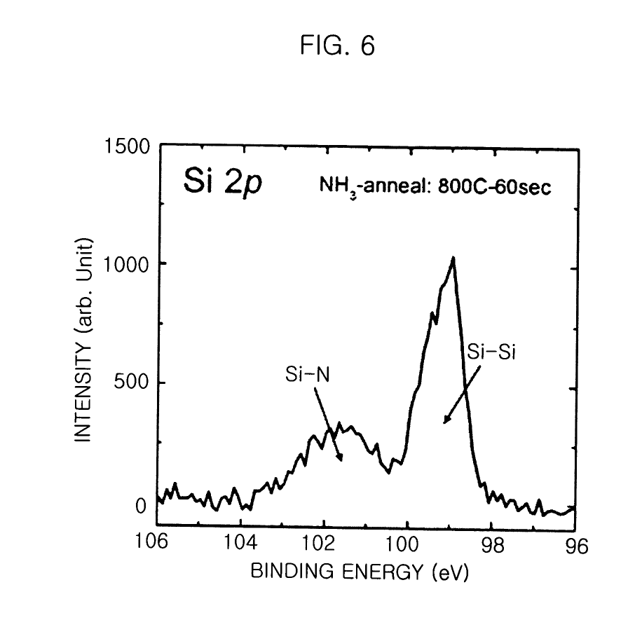

FIG. 6 is a graph illustrating a result of an x-ray photoelectron spectroscopy (hereinafter referred to as XPS) analysis on a thermal treatment after the polysilicon layer 33 deposition. The thermal treatment is performed at a temperature of about 800° C. for about 60 seconds in an atmosphere of NH₃. From the XPS analysis, it is discovered that a compositional ratio of nitrogen is about 15%. This value of the composition ratio is about 1×10¹⁵/cm² with respect to the surface density. Also, it is noted that the silicon nitride layer 34 deposited on the polysilicon layer 33 has a uniform thickness of about 2 nm.

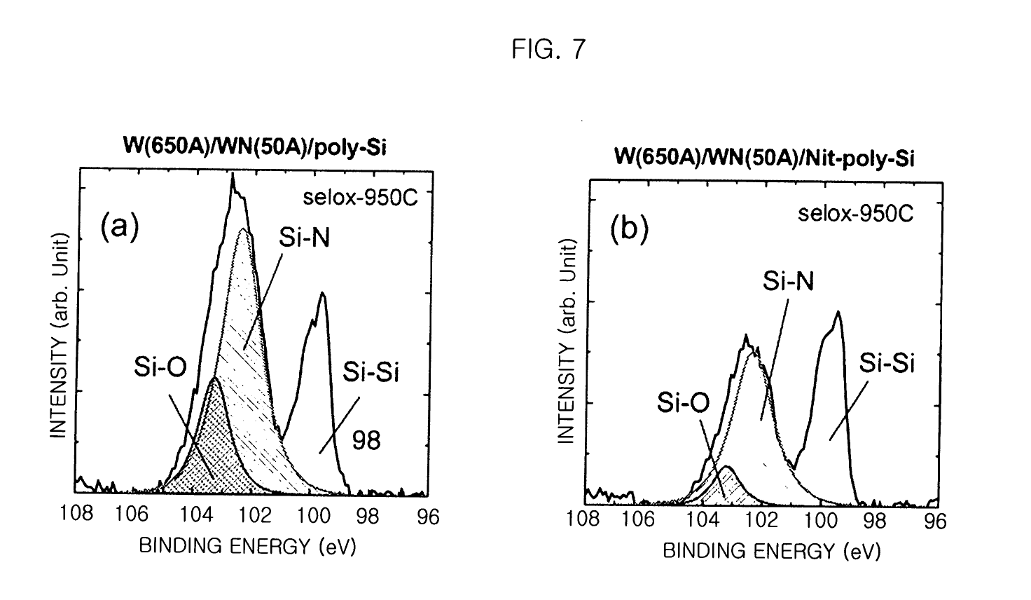

FIG. 7 are graphs for comparing an XPS analysis result on a stack structure of a tungsten layer, a tungsten nitride layer and a polysilicon layer with that on a stack structure of a tungsten layer, a tungsten nitride layer, a silicon nitride layer and a polysilicon layer. The above stack structure is obtained after the selective oxidation process performed at a temperature of about 950° C. The result shown in FIG. 7 is an XPS analysis of an upper portion of the polysilicon layer after the tungsten layer is etched in wet-type with use of H₂O₂. At this time, each of the tungsten layers has a thickness of about 650 Å, and each of the tungsten nitride layers has a thickness of about 50 Å.

As shown, the stack structure of the tungsten layer/tungsten nitride layer/polysilicon layer has a higher quantity of Si—O and Si—N than the stack structure of the tungsten layer/tungsten nitride layer/silicon nitride layer/polysilicon layer. The reason for this result is because of the tungsten silicide formed after the selective oxidation process. In more detail, the tungsten silicide causes the Si—O and the Si—N layers are additionally formed on an interface of the stack structure including the tungsten nitride layer/polysilicon layer.

By forming the silicon nitride layer having a thickness above about 1.2 nm at an interface between the polysilicon layer and the metal layer, it is possible to prevent the formation of non-uniform silicide layer at the interface between the polysilicon layer and the metal layer during the selective oxidation process and the thermal process. This effect further results in an improvement on reliability of the gate electrode.

While the present invention has been described with respect to certain preferred embodiments, it will be apparent to those skilled in the art that various changes and modifications may be made without departing from the scope of the invention as defined in the following claims.

What is claimed is:

1. A stack gate electrode of a semiconductor device, comprising:
a silicon layer;
a reaction prevention layer formed on the silicon layer, wherein the reaction prevention layer containing nitrogen and silicon and has a surface density of nitrogen above about 1×10¹⁵/cm²; and
a metal layer formed on the reaction prevention layer.

2. The stack gate electrode as recited in claim 1, wherein the reaction prevention layer has a thickness greater than about 1.2 nm but less than about 3 nm.

3. The stack gate electrode as recited in claim 1, wherein the metal layer includes:
a first layer containing refractory metal and nitrogen; and
a second layer made of the refractory metal used in the first layer.

4. The stack gate electrode as recited in claim 3, wherein the refractory metal is any one selected from a group consisting of W, Mo, Ta, Ti, Ni and Co.

5. The stack gate electrode as recited in claim 1, wherein the reaction prevention layer is a silicon nitride layer obtained by nitridating a surface of the silicon layer.

6. A method for fabricating a semiconductor device, comprising the steps of:
forming a semiconductor layer including at least a gate insulation layer;
forming a silicon layer on the gate insulation layer;
forming a reaction prevention layer on the silicon layer, the reaction prevention layer containing nitrogen and silicon and having a surface density of nitrogen above about 1×10¹⁵/cm²;
forming a metal layer on the reaction prevention layer;
forming a stack gate electrode by etching sequentially the metal layer, the reaction prevention layer and the silicon layer; and
performing a selective oxidation process oxidizing selectively the silicon layer from the stack gate electrode.

7. The method as recited in claim 6, wherein at the step of forming the reaction prevention layer, the silicon layer is formed by performing a decoupled plasma nitridation technique or a remote plasma nitridation technique in an atmosphere of a gas selected from a group consisting of NH₃, ND, where D is deuterium, N₂ and NF₃ or a mixed gas of the above as simultaneously as by maintaining a substrate temperature in a range from about 0° C. to about 700° C. and supplying a RF power of about 1000 W.

8. The method as recited in claim 6, wherein at the step of forming the reaction prevention layer, a surface of the silicon layer is proceeded with a thermal treatment performed at a temperature ranging from about 750° C. to about 950° C. for about 10 seconds to about 100 seconds in an atmosphere of NH₃ or ND₃.

9. The method as recited in claim 6, wherein the reaction prevention layer is a silicon nitride layer formed through the use of a chemical vapor deposition technique or an atomic layer deposition technique.

10. The method as recited in claim 6, wherein the reaction prevention layer is formed with a thickness thicker than about 1.2 nm but thinner than about 3 nm.
